(19) United States
(12) Patent Application Publication
(10) Pub. No.: US 2022/0238577 A1
(43) Pub. Date: Jul. 28, 2022

(54) IMAGING DEVICES WITH MULTI-PHASE GATED TIME-OF-FLIGHT PIXELS

(71) Applicant: SONY SEMICONDUCTOR SOLUTIONS CORPORATION, Kanagawa (JP)

(72) Inventors: Adarsh BASAVALINGAPPA, Fairport, NY (US); Frederick BRADY, Webster, NY (US)

(73) Assignee: SONY SEMICONDUCTOR SOLUTIONS CORPORATION, Kanagawa (JP)

(21) Appl. No.: 17/610,261

(22) PCT Filed: May 21, 2020
(86) PCT No.: PCT/IB2020/000407

§ 371 Date: Nov. 10, 2021

Related U.S. Application Data
(60) Provisional application No. 62/850,916, filed on May 21, 2019.

(51) Int. Cl. H01L 27/146

(52) U.S. Cl. CPC H01L 27/14607; H01L 27/14641; H01L 27/14612

(57) ABSTRACT

An imaging device includes a first pixel. The first pixel includes a first photoelectric conversion region, and first, second, third, and fourth transistors coupled to the first photoelectric conversion region and that transfer charge from the first photoelectric conversion region. In a plan view, gates of the first, second, third, and fourth transistors are arranged at a periphery of the first photoelectric conversion region in a first symmetrical pattern.

### FIELD

Example embodiments are directed to imaging devices, imaging apparatuses, and methods for operating the same, and more particularly, to imaging devices, imaging apparatuses, and methods for image sensing.

### BACKGROUND

Image sensing has applications in many fields, including object tracking, environment rendering, etc. Some image sensors employ time-of-flight (ToF) principles to detect a distance or depth to an object or objects within a scene. In general, a ToF depth sensor includes a light source and an imaging device including a plurality of pixels for sensing reflected light. In operation, the light source emits light (e.g., infrared light) toward an object or objects in the scene, and the pixels detect the light reflected from the object or objects. The elapsed time between the initial emission of the light and receipt of the reflected light by each pixel may correspond to a distance from the object or objects. Direct ToF imaging devices may measure the elapsed time itself to calculate the distance while indirect ToF imaging devices may measure the phase delay between the emitted light and the reflected light and translate the phase delay into a distance. The depth values of the pixels are then used by the imaging device to determine a distance to the object or objects, which may be used to create a three dimensional scene of the captured object or objects.

### SUMMARY

Example embodiments relate to imaging devices, imaging apparatuses, and methods thereof that allow for fast charge transfer from photodiodes to pixel circuits, fast overflow reset, etc.

At least one example embodiment is directed to an imaging device including a first pixel. The first pixel includes a first photoelectric conversion region, and first, second, third, and fourth transistors coupled to the first photoelectric conversion region and that transfer charge from the first photoelectric conversion region. In a plan view, gates of the first, second, third, and fourth transistors are arranged at a periphery of the first photoelectric conversion region in a first symmetrical pattern.

According to at least one example embodiment, the imaging device includes a second pixel including a second photoelectric conversion region. The second pixel includes fifth, and sixth, seventh, and eighth transistors coupled to the second photoelectric conversion region. In the plan view, gates of the fifth, sixth, seventh, and eighth transistors are arranged at a periphery of the second photoelectric conversion region in a second symmetrical pattern.

According to at least one example embodiment, in the plan view, pixel transistors of the first pixel and the second pixel are aligned with one another in a first direction. The pixel transistors include selection transistors, amplification transistors, and reset transistors.

According to at least one example embodiment, the first, second, third, fifth, sixth, and seventh transistors transfer charge of interest, and the fourth and eighth transistors transfer overflow charge.

According to at least one example embodiment, the first pixel and the second pixel are adjacent to one another such that the fourth transistor and the eighth transistor share drain regions.

According to at least one example embodiment, the first pixel and the second pixel have point symmetry.

According to at least one example embodiment, the first pixel includes a first amplification transistor that amplifies a signal output from the first transistor, and a second amplification transistor that amplifies a signal output from the second transistor. The first amplification transistor and the second amplification transistor share drain regions.

According to at least one example embodiment, the first pixel includes a third amplification transistor that amplifies a signal output from the third transistor, and the third amplification transistor and a fourth amplification transistor of another pixel different than the second pixel share drain regions.

According to at least one example embodiment, the first pixel further comprises fifth and sixth transistors coupled to the photoelectric conversion region and that transfer charge from the first photoelectric conversion region. In the plan view, the gates of the first, second, third, fourth transistors and gates of the fifth and sixth transistors are arranged at the periphery of the first photoelectric conversion region in a second symmetrical pattern that maintains the symmetry of the first symmetrical pattern.

According to at least one example embodiment, the first, second, third, and fourth transistors transfer charge of interest, and wherein the fifth and sixth transistors transfer overflow charge.

According to at least one example embodiment, the first pixel further comprises pixel transistors coupled to the first, second, third, and fourth transistors, and wherein, in the plan view, the pixel transistors and the first, second, third, fourth, fifth, and sixth transistors have line symmetry along a first direction and along a second direction perpendicular to the first direction.

According to at least one example embodiment, the gates of the first and second transistors are shorted to one another, and the gates of the third and fourth transistors are shorted to one another.

According to at least one example embodiment, the first, second, third, and fourth transistors are connected to respective signal lines that receive respective transfer signals having different phases, and the different phases are determined based on a driving signal that drives a light source.

According to at least one example embodiment, the first pixel further comprises wirings that electrically connect floating diffusions of the first pixel to respective amplification transistors of the first pixel. In the plan view, the wirings include dummy portions that extend beyond a connection point to the respective amplification transistors.

According to at least one example embodiment, the first, second, and third transistors are connected to respective signal lines that receive respective transfer signals having different phases. The different phases are determined based on a driving signal that drives a light source.

At least one example embodiment is directed to a system including a light source that emits light based on a driving signal, and an imaging device including a first pixel. The first pixel includes a first photoelectric conversion region that receives light emitted by the light source and reflected from an object, and first, second, and third, and fourth transistors coupled to the first photoelectric conversion region and that transfer charge from the first photoelectric conversion region. In a plan view, gates of the first, second, third, and fourth transistors are arranged at a periphery of the first photoelectric conversion region in a first symmetrical pattern.

According to at least one example embodiment, the first symmetrical pattern has line symmetry along a first direction and along a second direction perpendicular to the first direction.

According to at least one example embodiment, the first pixel further comprises fifth and sixth transistors coupled to the photoelectric conversion region and that transfer charge from the first photoelectric conversion region. In the plan view, the gates of the first, second, third, fourth transistors and gates of the fifth and sixth transistors are arranged at the periphery of the first photoelectric conversion region in a second symmetrical pattern that maintains the symmetry of the first symmetrical pattern.

At least one example embodiment is directed to an imaging device including a first pixel. The first includes a photoelectric conversion region, a plurality of pixel transistors, and at least four transistors that transfer charge from the photoelectric conversion region to respective ones of the plurality of pixel transistors. In a plan view, the at least four transistors and the plurality of pixel transistors have line symmetry along at least one direction.

### BRIEF DESCRIPTION OF THE DRAWINGS

FIG. 1 is a block diagram of an imaging device according to at least one example embodiment.

FIG. 2 illustrates an example schematic of a pixel according to at least one example embodiment.

FIG. 3 illustrates a layout for two pixels according to at least one example embodiment.

FIG. 4 illustrates a layout for a pixel according to at least one example embodiment.

FIG. 5 illustrates the layout of FIG. 3 in more detail according to at least one example embodiment.

FIG. 6 illustrates an example timing diagram for controlling the pixels in FIG. 3 according to at least one example embodiment.

FIG. 7 illustrates an example timing diagram for controlling the pixels in FIG. 3 according to at least one example embodiment.

FIG. 8 illustrates the layout of FIG. 4 in more detail according to at least one example embodiment.

FIG. 9 illustrates another example layout of FIG. 4 according to at least one example embodiment.

FIG. 10 illustrates an example timing diagram for controlling the pixel in FIG. 4 according to at least one example embodiment.

FIG. 11 illustrates an example timing diagram for controlling the pixel in FIG. 4 according to at least one example embodiment.

FIG. 12 illustrates the layout of FIG. 4 used in a two phase mode according to at least one example embodiment.

FIG. 13 illustrates another example of the layout of FIG. 4 used in a two phase mode according to at least one example embodiment.

FIG. 14 illustrates a timing diagram for controlling the pixel in FIGS. 12 and 13 according to at least one example embodiment.

FIG. 15 illustrates an example timing diagram for controlling the pixel in FIGS. 12 and 13 according to at least one example embodiment.

FIG. 16 is a block diagram illustrating an example of a ranging module according to at least one example embodiment.

FIG. 17 is a diagram illustrating use examples of an imaging device according to at least one example embodiment.

### DETAILED DESCRIPTION

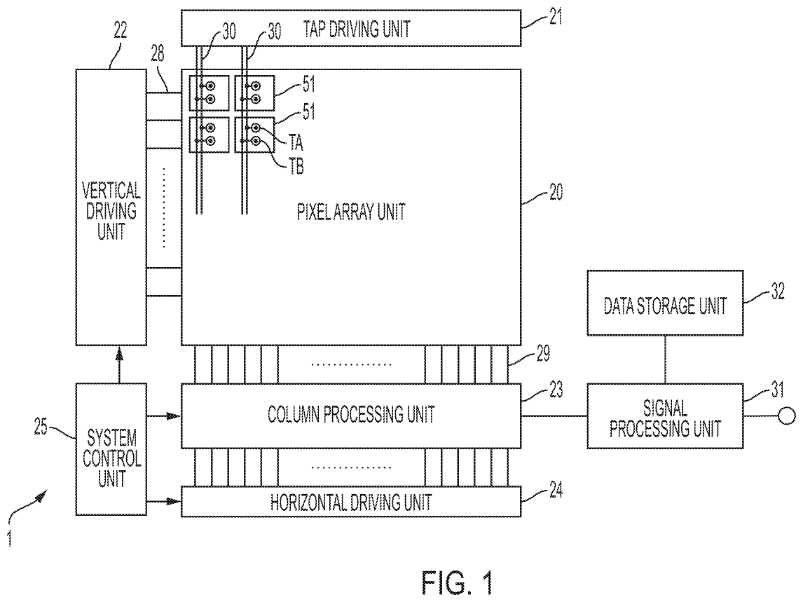

FIG. 1 is a block diagram of an imaging device according to at least one example embodiment.

The pixel 51 includes a photoelectric conversion region PD, such as a photodiode or other light sensor, transfer transistors TG0 and TG1, floating diffusion regions FD0 and FD1, reset transistors RST0 and RST1, amplification transistors AMP0 and AMP1, and selection transistors SEL0 and SEL1.

The imaging device 1 shown in FIG. 1 may be an imaging sensor of a front or rear surface irradiation type, and is provided, for example, in an imaging apparatus having a ranging function (or distance measuring function).

The imaging device 1 has a pixel array unit (or pixel array or pixel section) 20 formed on a semiconductor substrate (not shown) and a peripheral circuit integrated on the same semiconductor substrate the same as the pixel array unit 20. The peripheral circuit includes, for example, a tap driving unit (or tap driver) 21, a vertical driving unit (or vertical driver) 22, a column processing unit (or column processing circuit) 23, a horizontal driving unit (or horizontal driver) 24, and a system control unit (or system controller) 25.

The imaging device element 1 is further provided with a signal processing unit (or signal processor) 31 and a data storage unit (or data storage or memory or computer readable storage medium) 32. Note that the signal processing unit 31 and the data storage unit 32 may be mounted on the same substrate as the imaging device 1 or may be disposed on a substrate separate from the imaging device 1 in the imaging apparatus.

The pixel array unit 20 has a configuration in which pixels 51 that generate charge corresponding to a received light amount and output a signal corresponding to the charge are two-dimensionally disposed in a matrix shape of a row direction and a column direction. That is, the pixel array unit 20 has a plurality of pixels 51 that perform photoelectric conversion on incident light and output a signal corresponding to charge obtained as a result. Here, the row direction refers to an arrangement direction of the pixels 51 in a horizontal direction, and the column direction refers to the arrangement direction of the pixels 51 in a vertical direction. The row direction is a horizontal direction in the figure, and the column direction is a vertical direction in the figure.

The pixel 51 receives light incident from the external environment, for example, infrared light, performs photoelectric conversion on the received light, and outputs a pixel signal according to charge obtained as a result. The pixel 51 may include a first charge collector that detects charge obtained by the photoelectric conversion PD by applying a predetermined voltage (first voltage) to the pixel 51, and a second charge collector that detects charge obtained by the photoelectric conversion by applying a predetermined voltage (second voltage) to the pixel 51. The first and second charge collector may include tap A and tap B, respectively. Although two charge collectors are shown (i.e., tap A, and tap B), more or fewer charge collectors may be included according to design preferences. The first voltage and the second voltage may be applied to respective areas of the pixel near tap A and tap B to assist with channeling charge toward tap A and tap B during different time periods. The charge is then read out of each tap A and B with transfer signals GD, discussed in more detail below.

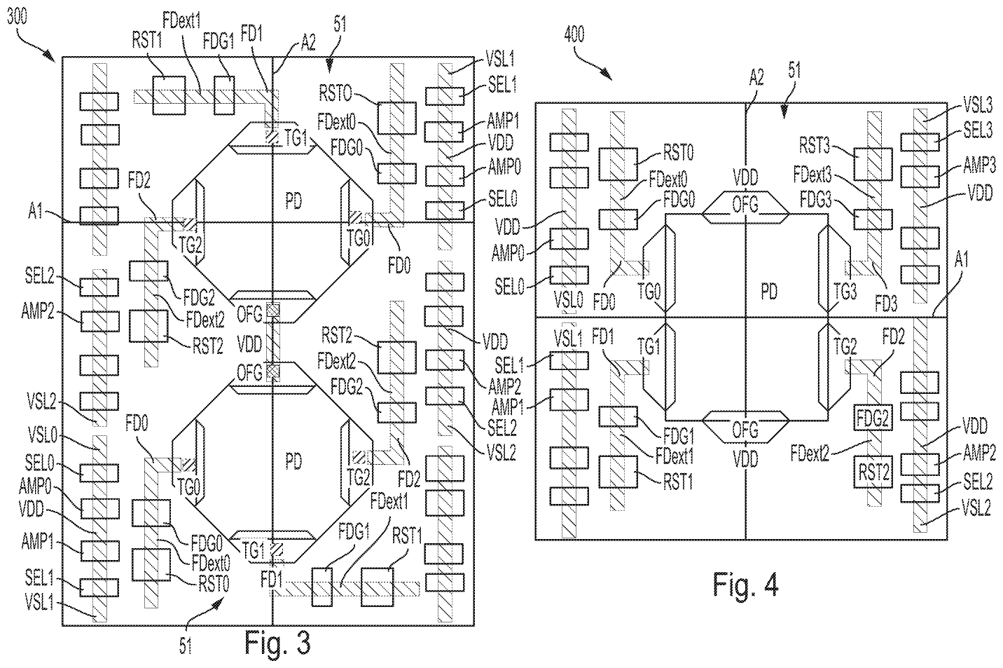

Although FIG. 1 illustrates two taps A/B, it should be appreciated that more or fewer taps and charge collectors may be included if desired, which may result in additional signal lines not shown in FIG. 1. For example, FIGS. 3-15 illustrate example embodiments that have more than two taps.

The tap driving unit 21 supplies the predetermined first voltage to the first charge collector of each of the pixels 51 of the pixel array unit 20 through a predetermined voltage supply line 30, and supplies the predetermined second voltage to the second charge collector thereof through the predetermined voltage supply line 30. Therefore, two voltage supply lines 30 including the voltage supply line 30 that transmits the first voltage and the voltage supply line 30 that transmits the second voltage are wired to one pixel column of the pixel array unit 20.

In the pixel array unit 20, with respect to the pixel array of the matrix shape, a pixel drive line 28 is wired along a row direction for each pixel row, and two vertical signal lines 29 are wired along a column direction for each pixel column. For example, the pixel drive line 28 transmits a drive signal for driving when reading a signal from the pixel. Note that, although FIG. 1 shows one wire for the pixel drive line 28, the pixel drive line 28 is not limited to one. One end of the pixel drive line 28 is connected to an output end corresponding to each row of the vertical driving unit 22.

The vertical driving unit 22 includes a shift register, an address decoder, or the like. The vertical driving unit 22 drives each pixel of all pixels of the pixel array unit 20 at the same time, or in row units, or the like. That is, the vertical driving unit 22 includes a driving unit that controls operation of each pixel of the pixel array unit 20, together with the system control unit 25 that controls the vertical driving unit 22.

The signals output from each pixel 51 of a pixel row in response to drive control by the vertical driving unit 22 are input to the column processing unit 23 through the vertical signal line 29. The column processing unit 23 performs a predetermined signal process on the pixel signal output from each pixel 51 through the vertical signal line 29 and temporarily holds the pixel signal after the signal process.

Specifically, the column processing unit 23 performs a noise removal process, a sample and hold (S/H) process, an analog to digital (AD) conversion process, and the like as the signal process.

The horizontal driving unit 24 includes a shift register, an address decoder, or the like, and sequentially selects unit circuits corresponding to pixel columns of the column processing unit 23. The column processing unit 23 sequentially outputs the pixel signals obtained through the signal process for each unit circuit, by a selective scan by the horizontal driving unit 24.

The system control unit 25 includes a timing generator or the like that generates various timing signals and performs drive control on the tap driving unit 21, the vertical driving unit 22, the column processing unit 23, the horizontal driving unit 24, and the like, on the basis of the various generated timing signals.

The signal processing unit 31 has at least a calculation process function and performs various signal processing such as a calculation process on the basis of the pixel signal output from the column processing unit 23. The data storage unit 32 temporarily stores data necessary for the signal processing in the signal processing unit 31. The signal processing unit 31 may control overall functions of the imaging device 1. For example, the tap driving unit 21, the vertical driving unit 22, the column processing unit 23, the horizontal driving unit 24, and the system control unit 25, and the data storage unit 32 may be under control of the signal processing unit 31. The signal processing unit or signal processor 31, alone or in conjunction with the other elements of FIG. 1, may control all operations of the systems discussed in more detail below with reference to the accompanying figures. Thus, the terms “signal processing unit” and “signal processor” may also refer to a collection of elements 21, 22, 23, 24, 25, and/or 31. A signal processor according to at least one example embodiment is capable of processing color information to produce a color information and depth information to produce a depth image.

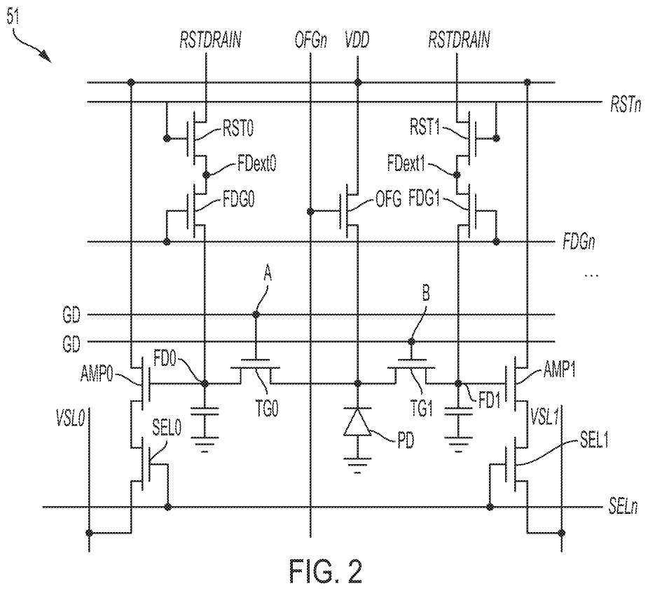

FIG. 2 illustrates an example schematic of a pixel 51 from FIG. 1. The pixel 51 includes a photoelectric conversion region PD, such as a photodiode or other light sensor, transfer transistors TG0 and TG1, floating diffusion regions FD0 and FD1, reset transistors RST0 and RST1, amplification transistors AMP0 and AMP1, and selection transistors SEL0 and SEL1. The pixel 51 may further include an overflow transistor OFG, transfer transistors FDG0 and FDG1, and floating diffusion regions FDext0 and FDext1.

The pixel 51 may be driven according to control signals or transfer signals GD applied to gates or taps A/B of transfer transistors TG0/TG1, reset signal RSTDRAIN, overflow signal OFGn, power supply signal VDD, selection signal SELn, and vertical selection signals VSL0 and VSL1. These signals are provided by various elements from FIG. 1, for example, the tap driver 21, vertical driver 22, system controller 25, etc.

As shown in FIG. 2, the transfer transistors TG0 and TG1 are coupled to the photoelectric conversion region PD and have taps A/B that transfer charge as a result of applying transfer signals.

These transfer signals GD may have different phases relative to a phase of a modulated signal from a light source (e.g., phases that differ 0 degrees, 90 degrees, 180 degrees, and/or 270 degrees, or alternatively, phases that differ by 120 degrees). The transfer signals may be applied in a manner that allows for depth information (or pixel values) to be captured in a desired number of frames (e.g., one frame, two frames, four frames, etc.). One of ordinary skill in the art would understand how to apply the transfer signals in order to use the collected charge to calculate a distance to an object. In at least one example embodiment, other transfer signals may be applied in a manner that allows for color information to be captured for a color image.

It should be appreciated that the transfer transistors FDG0/FDG1 and floating diffusions (or floating diffusion extensions) FDext0/FDext1 are included to expand the charge capacity of the pixel 51, if desired. However, these elements may be omitted or not used, if desired. The overflow transistor OFG is included to transfer overflow charge from the photoelectric conversion region PD, but may be omitted or unused if desired. Further still, if only one tap is desired, then elements associated with the other tap may be unused or omitted (e.g., TG1, FD1, FDG1, RST1, SEL1, AMP1).

Here, it should be appreciated that the pixel 51 includes identical sets of pixel elements that may be further replicated for each pixel 51 if desired. For example, elements TG0, FD0, FDG0, FDext0, RST0, SEL0, AMP0, VSL0 are considered as a first set of pixel elements, while TG1, FD1, FDG1, FDext1, RST1, SEL1, AMP1, and VSL1 are a second set of pixel elements that have the same structures, connections to one another, and functions as those in the first set of pixel elements. N sets of pixel elements TGn, FDn, FDextn, FDGn, RSTn, SELn, AMPn, and VSLn may be included as indicated by the ellipsis in FIG. 2. For example, FIGS. 3-17 illustrate pixels 51 that have third sets of elements and fourth sets of pixel elements.

Example embodiments will now be described with reference to FIGS. 3-17, which relate to pixel layouts and driving methods thereof that may reduce a footprint of a pixel, allow for substantially same charge transfer times for transfer transistors, provide improved depth sensing performance in bright ambient light conditions, and/or provide various operational modes.

FIGS. 3 and 4 illustrate inventive concepts according to at least one example embodiment.

In more detail, FIGS. 3 and 4 illustrate example pixels 51. Where reference to general element or set of elements is appropriate instead of a specific element, the description may refer to the element or set of elements by its root term. For example, when reference to a specific transfer transistor TG0, TG1, or TG2 is not necessary, the description may refer to the transfer transistor(s) “TG.”

FIG. 3 illustrates a layout 300 for two pixels 51, each pixel having a photoelectric conversion region PD, transfer transistors TG0, TG1, TG2, an overflow gate (or overflow transistor) OFG, reset transistors RST0, RST1, RST2, floating diffusions FD0, FD1, FD2 and FDext0, FDext1, FDext2, floating diffusion transistors FDG0, FDG1, FDG2, amplification transistors AMP0, AMP1, AMP2, and selection transistors SEL0, SEL 1, SEL2. Each selection transistor SEL0, SEL1, and SEL2 is connected to a respective signal lines VSL0, VSL1, and VSL2. The overflow transistors OFG may be transistors that provide for overflow of electric charge in bright ambient light conditions so that the ambient light has a reduced effect on the charge of interest collected by the FDs. In FIG. 3, the pixels 51 share a drain region for the two overflow transistors OFG that receives a power signal VDD to reduce a footprint of the pixels 51 within the imaging device 1. In addition, as discussed in more detail below, providing capacitance matched wirings and/or TGs and OFGs with a same or similar structure (e.g., similar structure for gates) allows for substantially uniform transfer speeds of charge across the TGs and OFGs. Further still, it should be appreciated that FIG. 3 facilitates the use of multiple phase shifted waveforms for collecting charge used to calculate depth information in a ToF or depth mode.

Each pixel 51 in FIG. 3 includes some elements that have symmetrical patterns and/or line symmetry along an axis A1 that extends horizontally and that passes through a center of the PD and/or along an axis A2 that extends vertically through the center of the PD. For example, along a vertical axis, line symmetry exists for amplification transistors AMP and selection transistors SEL on the left and right side of the figure (where unlabeled AMPs and SELs on the left side of the figure belong to an unillustrated neighboring pixel), and for transistors TG0/TG2. Similarly, along a horizontal axis, line symmetry exists for transistors OFG and TG1. In addition, the transistors TG0, TG1, TG2, and OFG for each pixel 51 are in a symmetrical pattern with gates have substantially same shapes.

Still further, it should be appreciated that the pixels 51 in FIG. 3, when considered together, have substantial point symmetry. This point symmetry may exist for all corresponding elements in each pixel 51. For example, using a center of FIG. 3 as a reference point (i.e., a central point that is located along the vertical line and located between each overflow transistor OFG), the corresponding elements of each pixel 51 are a same distance away from the reference point. For example, transistor TG1 of the top pixel 51 is a same distance away from the reference point as the transistor TG1 of the bottom pixel 51, selection transistor SEL1 of the top pixel 51 is a same distance away from the reference point as the selection transistor SEL1 of the bottom pixel 51, and so on.

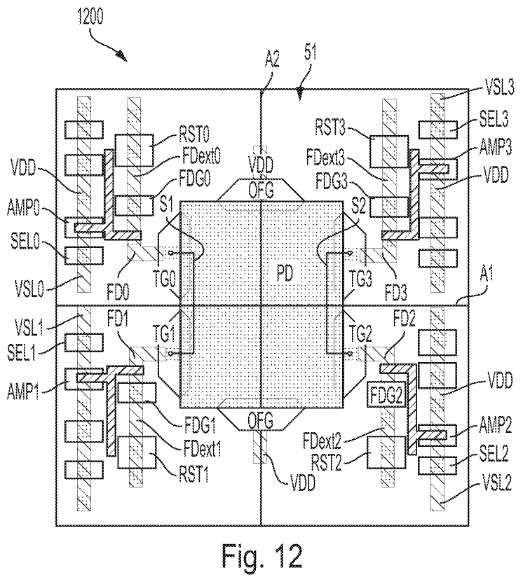

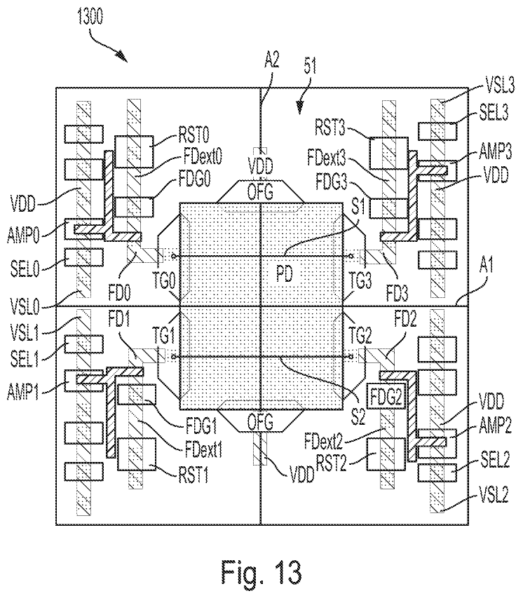

FIG. 4 illustrates a layout 400 for a pixel 51 having a photoelectric conversion region PD with four transfer transistors TG0 to TG3 and two overflow transistors OFG. FIG. 4 further shows floating diffusion regions FD0, FD1, FD2, FD3, and FDext0, FDext1, FDext2, FDext3, reset transistors RST0, RST1, RST2, RST3, amplification transistors AMP0, AMP1, AMP2, AMP3, and selection transistors SEL0, SEL1, SEL2, SEL3. Each selection transistor SEL0, SEL1, SEL2, and SEL3 is connected to a respective signal line VSL0, VSL1, VSL2, and VSl3. The pixel 51 of FIG. 4 has line symmetry in at least two directions shown by the axes A1 and A2 that pass through the PD. The TGs in FIG. 4 may allow for two modes, a fast mode in which each TG receives its own phase shifted transfer signal to transfer charge to a respective FD, and an increased sensitivity mode in which pairs of transfer transistors are shorted and supplied with a two phase transfer signal (see FIGS. 12 and 13). In the increased sensitivity mode, TG0 may be shorted to TG1 or TG3 and TG2 may be shorted to TG3 or TG1. As in FIG. 3, FIG. 4 provides capacitance matched wirings and/or TGs and OFGs with a same or similar structure (e.g., a same or similar structure for gates) to enable substantially uniform transfer speeds of charge across the TGs and OFGs. Further still, FIG. 4 facilitates the using multiple phase shifted waveforms for collecting charge used to calculate depth information in a ToF mode (e.g., two phase or four phase).

With reference to FIGS. 3 and 4, it should be appreciated that phases of transfer signals applied to TGs are with respect to a reference optical signal that is emitted toward an object and reflected back to the photoelectric conversion regions PDs for sensing by the PDs. Further, each transistor in FIGS. 3 and 4 may have one or more contacts to provide electric connection to signal lines (VSL signal lines shown, but other connections not shown are generally understood by one of ordinary skill in the art) of the imaging device 1 that control the transistors. In addition, it should be appreciated that the layouts of FIGS. 3 and 4 may provide for dual conversion gain with the inclusion of transistors FDG and floating diffusions FDext. In operation, access to additional charge storage is gained by turning on transistor FDG or is prevented by turning off transistor FDG. Further still, the photoelectric conversion regions PD in FIGS. 3 and 4 may have the octagonal/rectangle shapes shown or different shapes according to design preferences. It should be understood that the layouts 300 and 400 in FIGS. 3 and 4 may be repeated for all pixels in a respective pixel array. Thus, the unlabeled transistors of unillustrated pixels in each figure can be deduced from the labeled transistors in FIGS. 3 and 4.

The charge separation efficiency in each pixel, that is, modulation contrast between an active area and inactive area in a pixel is referred to as Cmod. In this case, an active area may be an area (doped area) of the pixel near a gate of a transistor TG or OFG that receives a signal to assist with channeling charge toward that transistor (instead the other transistors). In general, it is desired for Cmod to be high and/or matched between transistors to improve image quality. The symmetrical design pattern of transistors TG and OFG in FIGS. 3 and 4 allows for Cmod to be matched or closely matched.

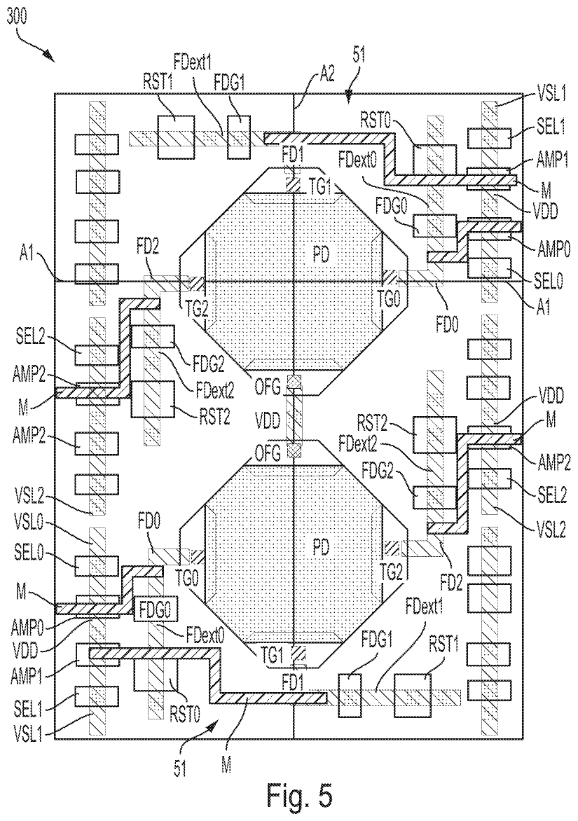

FIG. 5 illustrates the layout 300 of FIG. 3 in more detail. For example, FIG. 5 shows metal wirings M that may be used for making connections between elements of the imaging device 1. The metal wirings M may include extensions or dummy portions that are not necessarily required for making electrical contact, but that may be added to assist with matching a capacitance for FD-AMP connections. For example, in a case where the point of electrical contact to a gate of the amplification transistor is centered over (or under) the gate itself (i.e., the rectangular portion of AMP), the metal wirings M may extend beyond the contact point that electrically connects with the gate of the amplification transistor AMP. Although not explicitly shown, the metal wirings M may include other extension portions that branch from those shown in FIG. 5 in order to reach a desired matching for FD-AMP connections. For example, the metal wirings M may extend further than necessary to make electrical contact with each floating diffusion FD. The metal wirings M may be formed in a wiring layer M1 of the imaging device 1, where layer M1 may be a different layer than the layer(s) where the photoelectric conversion regions PD and gates/sources/drains of each transistor are disposed. Although metal is one example of a material used, another suitable conductor may also be used.

In addition, floating diffusions FDext may be connected to respective capacitors to enable a low conversion gain mode controlled by transistors FDG as explained above. In this case, the capacitance for FDext may comprise finger capacitors, metal-insulator-semiconductor (MIS) capacitors, metal-insulator-metal (MIM) capacitors, ONO or SONOS capacitors, trench capacitors that may also function as deep trench isolation between pixels, MRAM elements, and/or RERAMs.

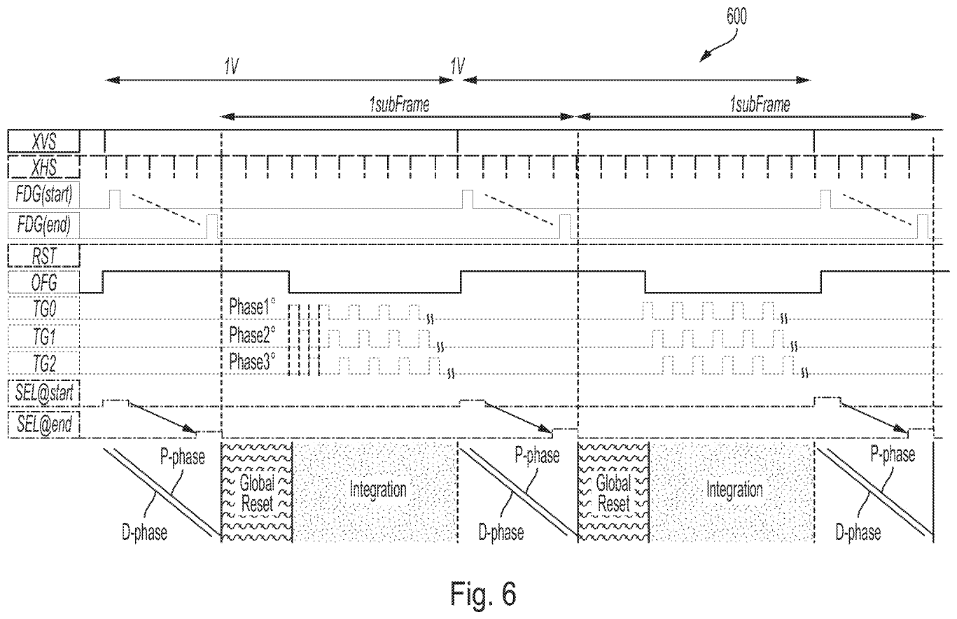

FIG. 6 illustrates an example timing diagram 600 for controlling the pixels 51 in FIG. 3 and/or FIG. 5 according to at least one example embodiment. As shown in FIG. 6, the transfer pulses for transfer transistors TG0, TG1, and TG2 do not overlap one another, and the timing of signals applied to transistors RST, FDG, SEL are further shown. Here, it should be understood that transfer signals for transfer transistors TG0, TG1, and TG2 may be generated according to a reference optical signal and are 120 degrees out of phase from one another. In FIG. 6 and other figures, the reset signal for transistor RST is always a logic high level because transistor FDG is used to control reset operations for floating diffusions FD. However, in the event that floating diffusions FDext are used, the reset transistor RST may be controlled in the same manner as the transistor FDG shown in FIG. 6 while transistor FDG may remain in a logic high state. FIG. 6 further illustrates a horizontal synchronization signal XHS to signify lines of a frame, and a vertical synchronization signal XVS to signify whole frames. As shown, the signals of interest are transferred from the photoelectric conversion region PD to floating diffusions FD during a subframe that begins with a global reset operation and terminates at an end of a D-phase/P-phase readout (where the D-phase readout corresponds to reading out reset levels of electric charge from the PD while the P-phase readout corresponds to reading out actual exposure levels of electric charge from the PD). A difference between the P-phase readout and the D-phase readout may correspond to the total level of charge collected by a photoelectric conversion region PD during the subframe.

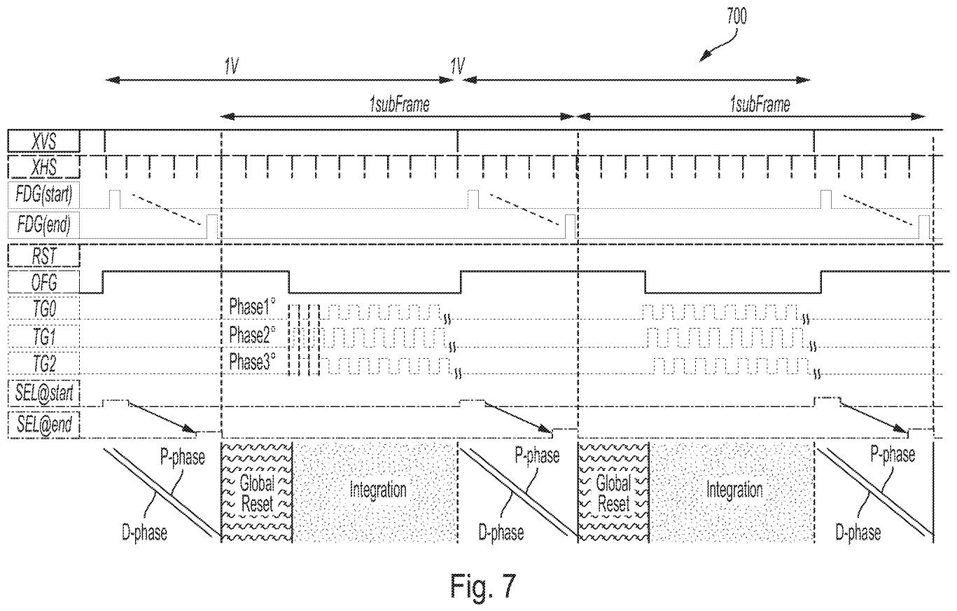

FIG. 7 illustrates an example timing diagram 700 for controlling the pixels 51 in FIG. 3 according to at least one example embodiment. FIG. 7 is substantially the same as FIG. 6 except the transfer pulses for transfer transistors TG0, TG1, and TG2 are overlapped with one another, which may improve the speed of transferring charge to respective floating diffusions FDs by taking advantage of the rise and fall times of the transfer signals. That is, in practice, the transfer signal pulses may not be perfect square pulses and instead may have a certain (e.g., known) rise time to reach a logical high level (rise time) and a certain (e.g., known) fall time to reach a logical low level. This allows transfer signal pulses to overlap one another with little or no interference, thereby shortening a length of a subframe.

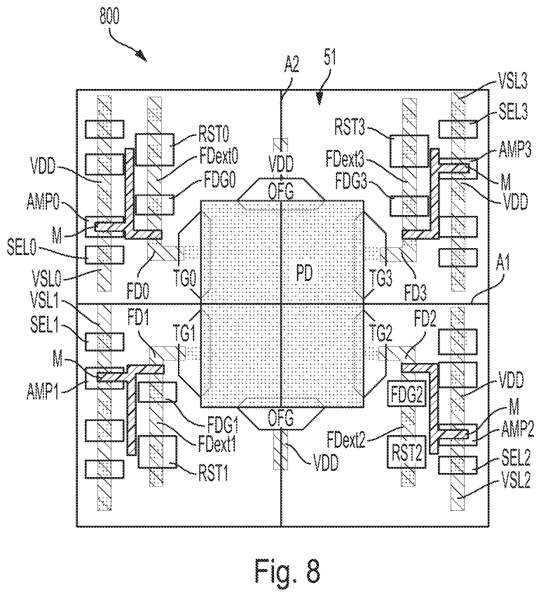

FIG. 8 illustrates the layout 400 of FIG. 4 in more detail.

For example, FIG. 8 shows metal wirings M that may include extensions or dummy portions that are added to assist with matching a capacitance for FD-AMP connections (as also in FIG. 5). In FIG. 8, the metal wirings include portions that extend in vertical directions beyond a point that is used for making electrical connection to a respective amplification transistor AMP. The metal wirings M may be formed in a wiring layer M1 of the imaging device 1. As in FIG. 5, the floating diffusions FDext in FIG. 8 may be connected to respective capacitors to enable a low conversion gain mode controlled by the transistor FDG as explained above. In this case, the capacitors may comprise finger capacitors, metal-insulator-semiconductor (MIS) capacitors, metal-insulator-metal (MIM) capacitors, ONO or SONOS capacitors, trench capacitors that may also function as deep trench isolation between pixels, MRAM elements, and/or RERAMs. As discussed with reference to FIG. 4, transfer transistors TGs may be shorted to one another create a two phase mode.

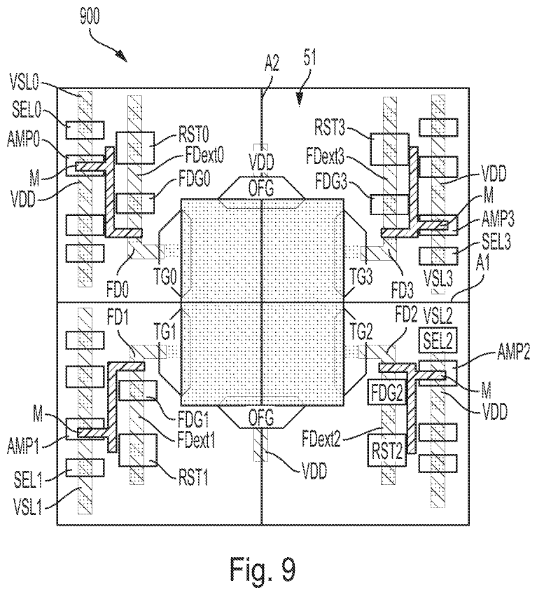

FIG. 9 illustrates an example layout 900 that is based on FIG. 4. FIG. 9 is substantially the same as FIG. 8 except that the metal wirings M have a different pattern than in FIG. 8. Specifically, the pixel 51 uses different amplification transistors AMP and selection transistors SEL than in FIG. 8, which changes the pattern of the metal wirings M. Using different amplification and selection transistors means that unillustrated neighboring pixels use the unlabeled selection and amplification transistors.

In view of FIGS. 8 and 9, it should be appreciated that the decision of which of the amplification transistors and selection transistors in FIGS. 5, 8, 9, 12, and 13 to use for a particular pixel may vary according to design choice.

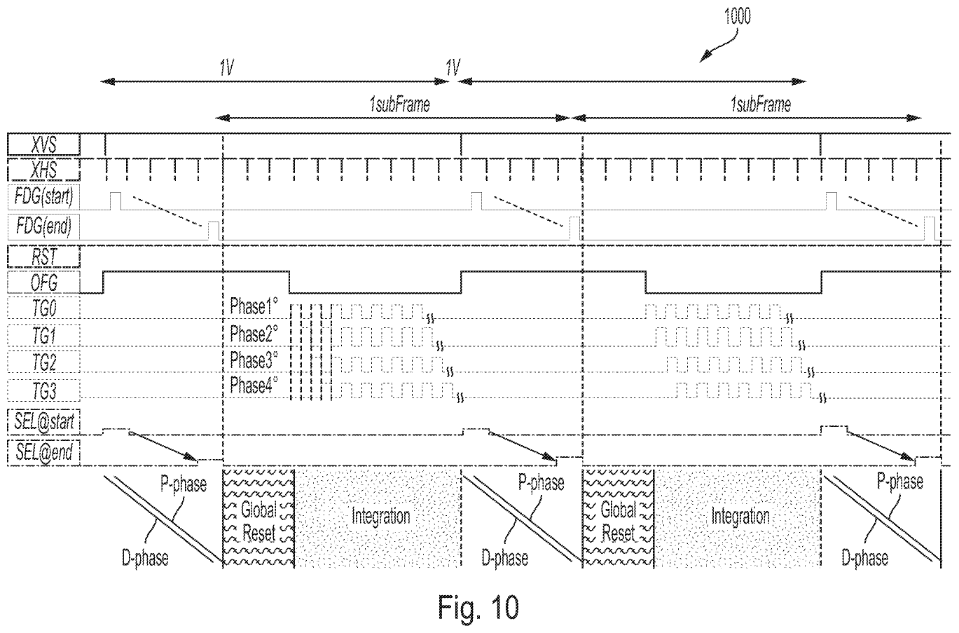

FIG. 10 illustrates an example timing diagram 1000 for controlling the pixel 51 in FIGS. 4, 8, and 9 according to at least one example embodiment. As shown in FIG. 10, the transfer pulses for transfer transistors TG0, TG1, TG2, and TG3 do not overlap one another, and the timing of signals applied to transistors RST, FDG, and SEL are further shown. Here, the transfer pulses for transfer transistors TG0, TG1, TG2, and TG3 are generated with respect to a reference optical signal and may be shifted 90 degrees from one another. FIG. 10 further illustrates a horizontal synchronization signal XHS to signify lines of a frame, and a vertical synchronization signal XVS to signify whole frames. As shown, the signals of interest are transferred from the photoelectric conversion region PD to floating diffusions FD during a subframe that begins with a global reset operation and terminates at an end of a D-phase/P-phase readout (where the D-phase readout corresponds to reading out reset levels of electric charge from the photoelectric conversion region PD while the P-phase readout corresponds to reading out actual exposure levels of electric charge from the photoelectric conversion region PD). A difference between the P-phase readout and the D-phase readout may correspond to the total level of charge collected by a photoelectric conversion region PD during the subframe.

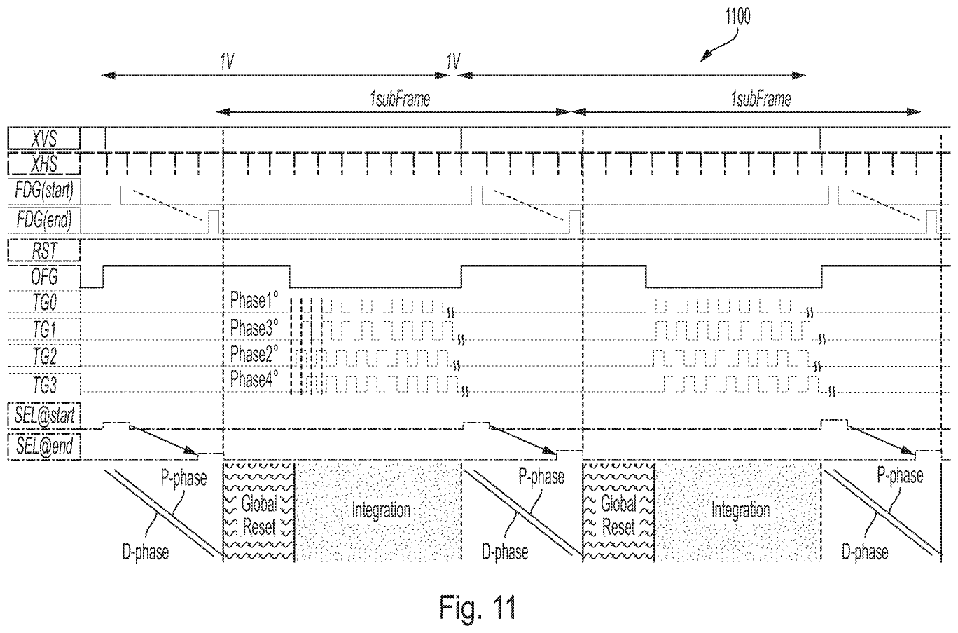

FIG. 11 illustrates an example timing diagram 1100 for controlling the pixel 51 in FIG. 4 according to at least one example embodiment. FIG. 11 is substantially the same as FIG. 10 except the transfer pulses for transfer transistors TG0, TG1, TG2, and TG3 are overlapped with one another, which may improve the speed of transferring charge to respective floating diffusions FD by taking advantage of the rise and fall times of the transfer signals. That is, in practice, the transfer signal pulses may not be perfect square pulses and instead may have a certain (e.g., known) rise time to reach a logical high level (rise time) and a certain (e.g., known) fall time to reach a logical low level. This allows transfer signal pulses to overlap one another without little or no interference, thereby shortening a length of a subframe.

FIG. 12 illustrates the layout 1200 of FIG. 4 used in a two phase mode. As noted above and illustrated with short wirings S1 and S2, transfer transistors TG may be shorted to one another to receive a same transfer signal pulse or, alternatively, receive a same transfer signal pulse through separate wirings as desired. In the example of FIG. 12, the left two transfer transistors TG0 receive a same first transfer signal and the right two transfer transistors TG1 receive a same second transfer signal. This mode may allow higher saturation capacity as a result of involving two floating diffusions FD for charge collection upon application of a transfer signal to two of the transfer transistors TG.

FIG. 13 illustrates another example of operating the layout 1300 of FIG. 4 in a two phase mode. In this example, the top two transfer transistors TG1 are shorted with short wirings S1 or, alternatively, receive a same transfer signal, and the bottom two transfer transistors TG0 are shorted with short wirings S2 or, alternatively, receive a same transfer signal.

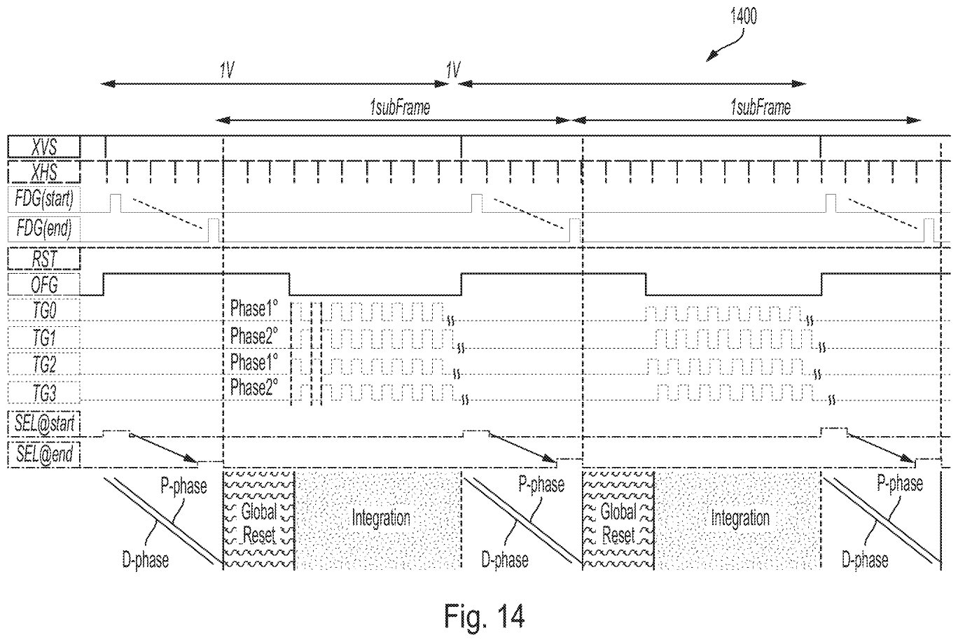

FIG. 14 illustrates a timing diagram 1400 for controlling the pixel in FIGS. 12 and 13 in a two phase mode. As shown in FIG. 14, transfer pulses for transfer transistors TG0 and TG1 do not overlap one another. Although not explicitly shown, it should be understood that phase 1 and phase 2 for transfer transistors TG0 and 1 may be out of phase by 180 degrees compared to a reference optical signal, in which case two pixels may be used to collect depth information in one frame (one pixel receiving transfer signals with zero degrees and 180 degrees phase shifts, and another pixel receiving transfer signals with 90 degrees and 270 degrees phase shifts). In another example embodiment, a same pixel may be used to collect depth information in two frames by applying transfer signals with 0 and 180 degree phase shifts in one frame, and applying transfer signals with 90 and 270 degree phase shifts in a next frame.

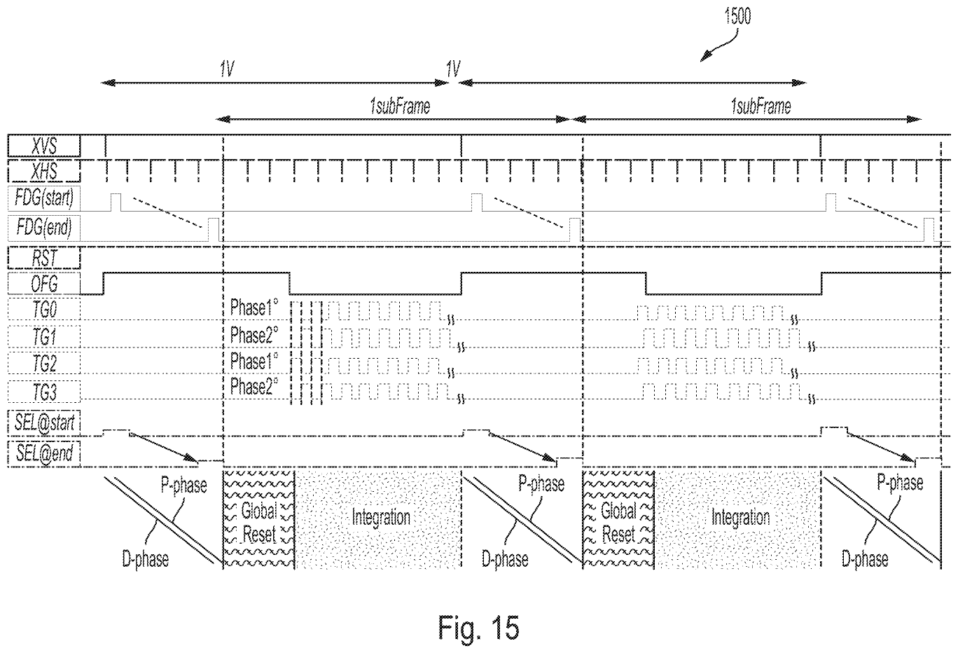

FIG. 15 illustrates an example timing diagram 1500 for controlling the pixel 51 in FIGS. 12 and 13 according to at least one example embodiment. FIG. 15 is substantially the same as FIG. 14 except the transfer pulses for transfer transistors TG0 and TG1 are overlapped with one another, which may improve the speed of transferring charge to respective floating diffusions FD by taking advantage of the rise and fall times of the transfer signals. That is, in practice, the transfer signal pulses may not be perfect square pulses and instead may have a certain (e.g., known) rise time to reach a logical high level (rise time) and a certain (e.g., known) fall time to reach a logical low level. This allows transfer signal pulses to overlap one another without little or no interference, thereby shortening a length of a subframe. Although not explicitly shown, it should be understood that phase 1 and phase 2 for transfer transistors TGs 0 and 1 may be out of phase by 180 degrees compared to a reference optical signal, in which case two pixels may be used to collect depth information in one frame (one pixel receiving transfer signals with zero degrees and 180 degrees phase shifts, and another pixel receiving transfer signals with 90 degrees and 270 degrees phase shifts). In another example embodiment, a same pixel may be used to collect depth information in two frames by applying transfer signals with 0 and 180 degree phase shifts in one frame, and applying transfer signals with 90 and 270 degree phase shifts in a next frame.

In FIGS. 3, 4, 5, 8, 9, 12, and 13, it should be understood that unlabeled transistors correspond to transistors that belong to unillustrated neighboring pixels that have the same layout as the pixels illustrated in FIGS. 3 and 4. It should be further understood that FIGS. 3, 4 5, 8, 9, 12, and 13 show substantially accurate relative positional relationships of the elements depicted therein and can be relied upon as support for such positional relationships. For example, the figures provide support for selection transistors SEL and amplification transistors AMP being aligned with one another in a vertical direction, while transistors FDG and RST are aligned with one another in the vertical direction. As another example, the figures provide support for a transistor on a right side of a figure being aligned with a transistor on a left side of a figure in the horizontal direction. As yet another example, the figures are generally accurate with respect to showing positions of overlapping elements.

It should further be appreciated that a distance to an object may be calculated for each pixel according to known techniques based on the charge transferred from the photoelectric conversion regions PD according to the timing diagrams above. One such method is set forth below with Equation (1):

$$Distance = \frac{C \cdot Δ T}{2} = \frac{C \cdot α}{4 π {f}_{mod}} \\ α = arctan ( \frac{{ϕ}_{1} - {ϕ}_{3}}{{ϕ}_{0} - {ϕ}_{2}} ) \qquad ( 1 )$$

Here, C is the speed of light, ΔT is the time delay, fmod is the modulation frequency of the emitted light or reference optical signal, ϕ0 to ϕ3 are the signal values detected with transfer signals having phase differences from the emitted light 0 degrees, 90 degrees, 180 degrees, and 270 degrees, respectively. One of ordinary skill in the art would also know how to calculate a distance to the object with three signal values detected with transfer signals having 120 degree phase differences from one another.

Systems/devices that may incorporate the above described imaging devices will now be described.

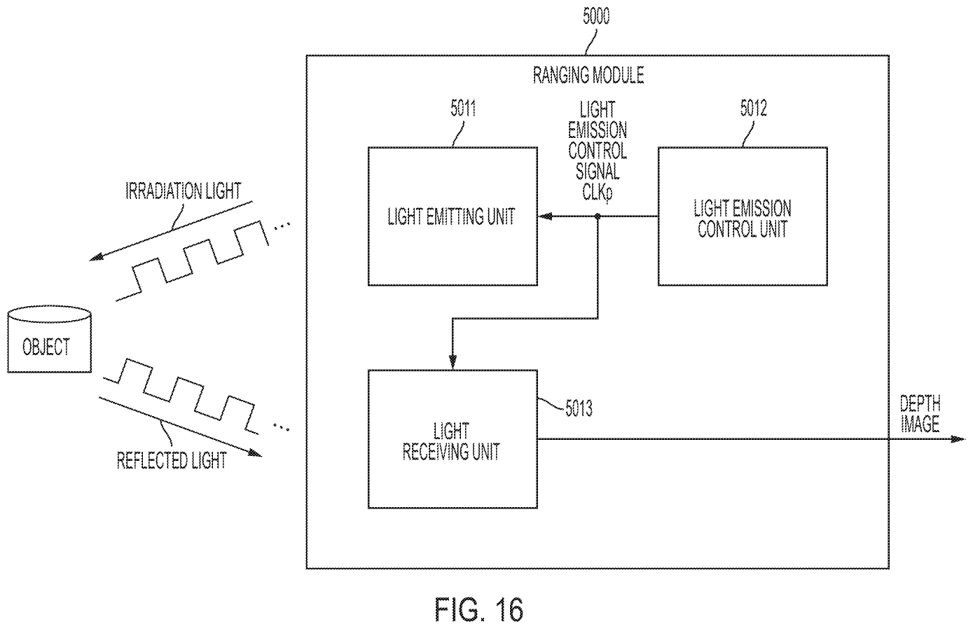

FIG. 16 is a block diagram illustrating an example of a ranging module according to at least one example embodiment.

The ranging module 5000 includes a light emitting unit 5011, a light emission control unit 5012, and a light receiving unit 5013.

The light emitting unit 5011 has a light source that emits light having a predetermined wavelength, and irradiates the object with irradiation light of which brightness periodically changes. For example, the light emitting unit 5011 has a light emitting diode that emits infrared light having a wavelength in a range of 780 nm to 1000 nm as a light source, and generates the irradiation light in synchronization with a light emission control signal CLKp of a rectangular wave supplied from the light emission control unit 5012.

Note that, the light emission control signal CLKp is not limited to the rectangular wave as long as the control signal CLKp is a periodic signal. For example, the light emission control signal CLKp may be a sine wave.

The light emission control unit 5012 supplies the light emission control signal CLKp to the light emitting unit 5011 and the light receiving unit 5013 and controls an irradiation timing of the irradiation light. A frequency of the light emission control signal CLKp is, for example, 20 megahertz (MHz). Note that, the frequency of the light emission control signal CLKp is not limited to 20 megahertz (MHz), and may be 5 megahertz (MHz) or the like.

The light receiving unit 5013 receives reflected light reflected from the object, calculates the distance information for each pixel according to a light reception result, generates a depth image in which the distance to the object is represented by a gradation value for each pixel, and outputs the depth image.

The above-described imaging device 1 is used for the light receiving unit 5013, and for example, the imaging device 1 serving as the light receiving unit 5013 calculates the distance information for each pixel from a signal intensity detected by each tap, on the basis of the light emission control signal CLKp.

As described above, the imaging device 1 shown in FIG. 1 is able to be incorporated as the light receiving unit 5013 of the ranging module 5000 that obtains and outputs the information associated with the distance to the subject by the indirect ToF method. By adopting the imaging device 1 of one or more of the embodiments described above, it is possible to improve one or more distance measurement characteristics of the ranging module 5000 (e.g., distance accuracy, speed of measurement, and/or the like).

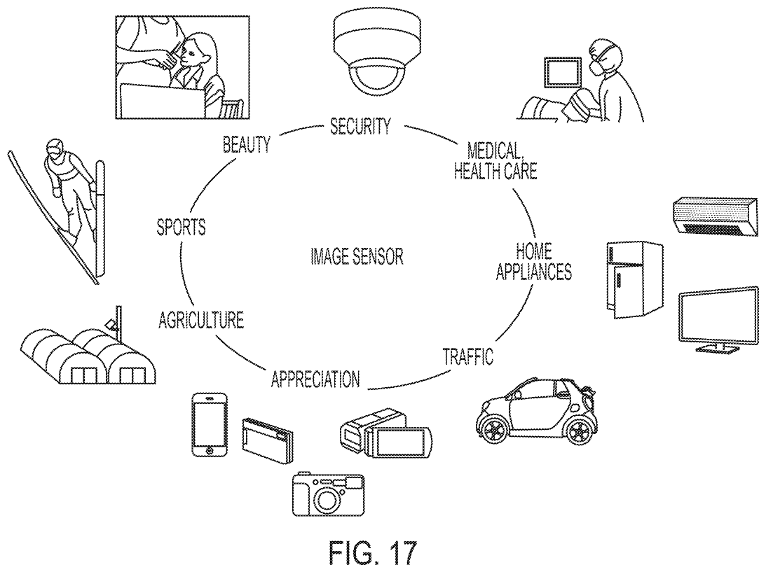

FIG. 17 is a diagram illustrating use examples of an imaging device 1 according to at least one example embodiment.

For example, the above-described imaging device 1 (image sensor) can be used in various cases of sensing light such as visible light, infrared light, ultraviolet light, and X-rays as described below. The imaging device 1 may be included in apparatuses such as a digital still camera and a portable device with a camera function which capture images, apparatuses for traffic such as an in-vehicle sensor that captures images of a vehicle to enable automatic stopping, recognition of a driver state, measuring distance, and the like. The imaging device 1 may be included in apparatuses for home appliances such as a TV, a refrigerator, and an air-conditioner in order to photograph a gesture of a user and to perform an apparatus operation in accordance with the gesture. The imaging device 1 may be included in apparatuses for medical or health care such as an endoscope and an apparatus that performs angiography through reception of infrared light. The imaging device 1 may be included in apparatuses for security such as a security monitoring camera and a personal authentication camera. The imaging device 1 may be included in an apparatus for beauty such as a skin measuring device that photographs skin. The imaging device 1 may be included in apparatuses for sports such as an action camera, a wearable camera for sports, and the like. The imaging device 1 may be included in apparatuses for agriculture such as a camera for monitoring a state of a farm or crop.

Example embodiments relate to imaging devices, imaging apparatuses, and methods thereof that allow for fast charge transfer from photodiodes to pixel circuits, fast overflow reset, etc. Example embodiments further provide pixels capable of detecting light in multiple modes in a manner that reduces an overall footprint of a pixel array. Symmetrical gates of transfer transistors and capacitance matched wirings allow for matched charge transfer times and/or matched Cmod. Overflow transistors OFG provide for improved performance in high ambient light. Drain sharing for transistors further reduces the footprint of the pixel array.

Example embodiments will now be described with reference to FIGS. 1-17.

At least one example embodiment is directed to an imaging device 1 including a first pixel 51. The first pixel 51 includes a first photoelectric conversion region PD, and first, second, third, and fourth transistors TG0/TG1/TG2 and TG3 or OFG coupled to the first photoelectric conversion region PD and that transfer charge from the first photoelectric conversion region PD. In a plan view, gates of the first, second, third, and fourth transistors are arranged at a periphery of the first photoelectric conversion region in a first symmetrical pattern (FIGS. 3 and 4).

According to at least one example embodiment, the imaging device includes a second pixel 51 including a second photoelectric conversion region PD. The second pixel includes fifth, and sixth, seventh, and eighth TG1/TG2/TG3 and TG4 or OFG transistors coupled to the second photoelectric conversion region PD. In the plan view, gates of the fifth, sixth, seventh, and eighth transistors are arranged at a periphery of the second photoelectric conversion region PD in a second symmetrical pattern.

According to at least one example embodiment, in the plan view, pixel transistors of the first pixel 51 and the second pixel 51 are aligned with one another in a first direction. For example, the aligned pixel transistors include selection transistors SEL, amplification transistors AMP, and reset transistors RST.

According to at least one example embodiment, the first, second, third, fifth, sixth, and seventh transistors TG transfer charge of interest, and the fourth and eighth transistors OFG transfer overflow charge.

According to at least one example embodiment, the first pixel 51 and the second pixel 51 are adjacent to one another such that the fourth transistor OFG and the eighth transistor OFG share drain regions.

According to at least one example embodiment, the first pixel 51 and the second pixel 51 have point symmetry, for example, in FIG. 3.

According to at least one example embodiment, the first pixel 51 includes a first amplification transistor AMP0 that amplifies a signal output from the first transistor TG0, and a second amplification transistor AMP1 that amplifies a signal output from the second transistor TG1. In FIG. 3, for example, the first amplification transistor AMP0 and the second amplification transistor AMP1 share drain regions.

According to at least one example embodiment, the first pixel 51 includes a third amplification transistor AMP2 that amplifies a signal output from the third transistor TG2, and the third amplification transistor AMP2 and a fourth amplification transistor (not labeled) of another pixel different than the second pixel share drain regions.

According to at least one example embodiment, the first pixel 51 further comprises fifth and sixth transistors OFGs coupled to the photoelectric conversion region PD and that transfer charge from the first photoelectric conversion region. In the plan view, the gates of the first, second, third, fourth transistors TG0 to TG3 and gates of the fifth and sixth transistors OFG are arranged at the periphery of the first photoelectric conversion region PD in a second symmetrical pattern that maintains the symmetry of the first symmetrical pattern. For example, the first symmetrical pattern is the pattern created by the layout of TG0 to TG3, while the second symmetrical pattern is created by adding two transistors OFG. According to at least one example embodiment, the first, second, third, and fourth transistors TG0 to TG3 transfer charge of interest, and wherein the fifth and sixth transistors OFG transfer overflow charge.

According to at least one example embodiment, the first pixel 51 further comprises pixel transistors FDG, AMP, SEL, RST coupled to the first, second, third, and fourth transistors TG0 to TG3, and wherein, in the plan view, the pixel transistors and the first, second, third, fourth, fifth, and sixth transistors have line symmetry along a first direction and along a second direction perpendicular to the first direction.

According to at least one example embodiment, the gates of the first and second transistors (e.g., TG0/TG1 or TG1/TG2) are shorted to one another, and the gates of the third and fourth transistors (e.g., TG2/TG3 or TG0/TG3) are shorted to one another.

According to at least one example embodiment, the first, second, third, and fourth transistors are connected to respective signal lines that receive respective transfer signals having different phases, and the different phases are determined based on a driving signal that drives a light source (see, e.g., the timing diagrams in FIGS. 10, 11, 14, and 15).

According to at least one example embodiment, the first pixel 51 further comprises wirings M that electrically connect floating diffusions FD of the first pixel to respective amplification transistors AMP of the first pixel 51. In the plan view, the wirings include dummy portions that extend beyond a connection point to the respective amplification transistors AMP.

According to at least one example embodiment, the first, second, and third transistors TG0 to TG2 are connected to respective signal lines that receive respective transfer signals having different phases (see, for example, FIGS. 6 and 7). The different phases are determined based on a driving signal that drives a light source.

At least one example embodiment is directed to a system including a light source 5011 that emits light based on a driving signal, and an imaging device including a first pixel. The first pixel includes a first photoelectric conversion region that receives light emitted by the light source and reflected from an object, and first, second, and third, and fourth transistors (TG0 to TG2 and OFG, or TG0 to TG3) coupled to the first photoelectric conversion region and that transfer charge from the first photoelectric conversion region. In a plan view, gates of the first, second, third, and fourth transistors are arranged at a periphery of the first photoelectric conversion region in a first symmetrical pattern.

According to at least one example embodiment, the first symmetrical pattern has line symmetry along a first direction and along a second direction perpendicular to the first direction (see FIG. 4).

According to at least one example embodiment, the first pixel 51 further comprises fifth and sixth transistors OFG coupled to the first photoelectric conversion region PD and that transfer charge from the first photoelectric conversion region PD. In the plan view, the gates of the first, second, third, fourth transistors TG0 to TG3 and gates of the fifth and sixth transistors OFG are arranged at the periphery of the first photoelectric conversion region PD in a second symmetrical pattern that maintains the symmetry of the first symmetrical pattern.

At least one example embodiment is directed to an imaging device 1 including a first pixel 51. The first includes a photoelectric conversion region PD, a plurality of pixel transistors (AMP, SEL, FDG, RST), and at least four transistors (TG0 to TG3, or TG0 to TG2 and OFG) that transfer charge from the photoelectric conversion region PD to respective ones of the plurality of pixel transistors. In a plan view, the at least four transistors and the plurality of pixel transistors have line symmetry along at least one direction.

Any processing devices, control units, processing units, etc. discussed above may correspond to one or many computer processing devices, such as a Field Programmable Gate Array (FPGA), an Application-Specific Integrated Circuit (ASIC), any other type of Integrated Circuit (IC) chip, a collection of IC chips, a microcontroller, a collection of microcontrollers, a microprocessor, Central Processing Unit (CPU), a digital signal processor (DSP) or plurality of microprocessors that are configured to execute the instructions sets stored in memory.

As will be appreciated by one skilled in the art, aspects of the present disclosure may be illustrated and described herein in any of a number of patentable classes or context including any new and useful process, machine, manufacture, or composition of matter, or any new and useful improvement thereof. Accordingly, aspects of the present disclosure may be implemented entirely hardware, entirely software (including firmware, resident software, micro-code, etc.) or combining software and hardware implementation that may all generally be referred to herein as a “circuit,” “module,” “component,” or “system.” Furthermore, aspects of the present disclosure may take the form of a computer program product embodied in one or more computer readable media having computer readable program code embodied thereon.

Any combination of one or more computer readable media may be utilized. The computer readable media may be a computer readable signal medium or a computer readable storage medium. A computer readable storage medium may be, for example, but not limited to, an electronic, magnetic, optical, electromagnetic, or semiconductor system, apparatus, or device, or any suitable combination of the foregoing. More specific examples (a non-exhaustive list) of the computer readable storage medium would include the following: a portable computer diskette, a hard disk, a random access memory (RAM), a read-only memory (ROM), an erasable programmable read-only memory (EPROM or Flash memory), an appropriate optical fiber with a repeater, a portable compact disc read-only memory (CD-ROM), an optical storage device, a magnetic storage device, or any suitable combination of the foregoing. In the context of this document, a computer readable storage medium may be any tangible medium that can contain or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device. Program code embodied on a computer readable signal medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Scala, Smalltalk, Eiffel, JADE, Emerald, C++, C#, VB.NET, Python or the like, conventional procedural programming languages, such as the “C” programming language, Visual Basic, Fortran 2003, Perl, COBOL 2002, PHP, ABAP, dynamic programming languages such as Python, Ruby and Groovy, or other programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider) or in a cloud computing environment or offered as a service such as a Software as a Service (SaaS).

Aspects of the present disclosure are described herein with reference to flowchart illustrations and/or block diagrams of methods, apparatuses (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable instruction execution apparatus, create a mechanism for implementing the functions/acts specified in the flowchart and/or block diagram block or blocks.

These computer program instructions may also be stored in a computer readable medium that when executed can direct a computer, other programmable data processing apparatus, or other devices to function in a particular manner, such that the instructions when stored in the computer readable medium produce an article of manufacture including instructions which when executed, cause a computer to implement the function/act specified in the flowchart and/or block diagram block or blocks. The computer program instructions may also be loaded onto a computer, other programmable instruction execution apparatus, or other devices to cause a series of operational steps to be performed on the computer, other programmable apparatuses or other devices to produce a computer implemented process such that the instructions which execute on the computer or other programmable apparatus provide processes for implementing the functions/acts specified in the flowchart and/or block diagram block or blocks.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted that the terms “comprising,” “including,” and “having” can be used interchangeably.

The foregoing discussion has been presented for purposes of illustration and description. The foregoing is not intended to limit the disclosure to the form or forms disclosed herein. In the foregoing Detailed Description for example, various features of the disclosure are grouped together in one or more aspects, embodiments, and/or configurations for the purpose of streamlining the disclosure. The features of the aspects, embodiments, and/or configurations of the disclosure may be combined in alternate aspects, embodiments, and/or configurations other than those discussed above. This method of disclosure is not to be interpreted as reflecting an intention that the claims require more features than are expressly recited in each claim. Rather, as the following claims reflect, inventive aspects lie in less than all features of a single foregoing disclosed aspect, embodiment, and/or configuration. Thus, the following claims are hereby incorporated into this Detailed Description, with each claim standing on its own as an embodiment of the disclosure.

Moreover, though the description has included description of one or more aspects, embodiments, and/or configurations and certain variations and modifications, other variations, combinations, and modifications are within the scope of the disclosure, e.g., as may be within the skill and knowledge of those in the art, after understanding the present disclosure. It is intended to obtain rights which include alternative aspects, embodiments, and/or configurations to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

Example embodiments may be configured according to the following:

(1) An imaging device, comprising:

a first pixel including:
a first photoelectric conversion region; and
first, second, third, and fourth transistors coupled to the first photoelectric conversion region and that transfer charge from the first photoelectric conversion region,

wherein, in a plan view, gates of the first, second, third, and fourth transistors are arranged at a periphery of the first photoelectric conversion region in a first symmetrical pattern.

(2) The imaging device of (1), further comprising:

a second pixel including:
a second photoelectric conversion region; and
fifth, and sixth, seventh, and eighth transistors coupled to the second photoelectric conversion region,

wherein, in the plan view, gates of the fifth, sixth, seventh, and eighth transistors are arranged at a periphery of the second photoelectric conversion region in a second symmetrical pattern.

(3) The imaging device of one or more of (1) to (2), wherein, in the plan view, pixel transistors of the first pixel and the second pixel are aligned with one another in a first direction.
(4) The imaging device of one or more of (1) to (3), wherein the pixel transistors include selection transistors, amplification transistors, and reset transistors.
(5) The imaging device one of or more of (1) to (4), wherein the first, second, third, fifth, sixth, and seventh transistors transfer charge of interest, and wherein the fourth and eighth transistors transfer overflow charge.
(6) The imaging device of one or more of (1) to (5), wherein the first pixel and the second pixel are adjacent to one another such that the fourth transistor and the eighth transistor share drain regions.
(7) The imaging device of one or more of (1) to (6), wherein the first pixel and the second pixel include pixel transistors with point symmetry.
(8) The imaging device of one or more of (1) to (7), wherein the first pixel includes a first amplification transistor that amplifies a signal output from the first transistor, and a second amplification transistor that amplifies a signal output from the second transistor, and wherein the first amplification transistor and the second amplification transistor share drain regions.
(9) The imaging device of one or more of (1) to (8), wherein the first pixel includes a third amplification transistor that amplifies a signal output from the third transistor, and wherein the third amplification transistor and a fourth amplification transistor of another pixel different than the second pixel share drain regions.
(10) The imaging device of one or more of (1) to (9), wherein the first pixel further comprises:

fifth and sixth transistors coupled to the photoelectric conversion region and that transfer charge from the first photoelectric conversion region, wherein, in the plan view, the gates of the first, second, third, fourth transistors and gates of the fifth and sixth transistors are arranged at the periphery of the first photoelectric conversion region in a second symmetrical pattern that maintains the symmetry of the first symmetrical pattern.

(11) The imaging device of one or more of (1) to (10), wherein the first, second, third, and fourth transistors transfer charge of interest, and wherein the fifth and sixth transistors transfer overflow charge.
(12) The imaging device of one or more of (1) to (11), wherein the first pixel further comprises pixel transistors coupled to the first, second, third, and fourth transistors, and wherein, in the plan view, the pixel transistors and the first, second, third, fourth, fifth, and sixth have line symmetry along a first direction and along a second direction perpendicular to the first direction.
(13) The imaging device of one or more of (1) to (12), wherein the gates of the first and second transistors are shorted to one another, and wherein the gates of the third and fourth transistors are shorted to one another.
(14) The imaging device of one or more of (1) to (13), wherein the first, second, third, and fourth transistors are connected to respective signal lines that receive respective transfer signals having different phases, wherein the different phases are determined based on a driving signal that drives a light source.
(15) The imaging device of one or more of (1) to (14), wherein the first pixel further comprises wirings that electrically connect floating diffusions of the first pixel to respective amplification transistors of the first pixel, and wherein, in the plan view, the wirings include dummy portions that extend beyond a connection point to the respective amplification transistors.
(16) The imaging device of one or more of (1) to (15), wherein the first, second, and third transistors are connected to respective signal lines that receive respective transfer signals having different phases, wherein the different phases are determined based on a driving signal that drives a light source.
(17) A system comprising:
a light source that emits light based on a driving signal;
an imaging device, comprising:

a first pixel including:
a first photoelectric conversion region that receives light emitted by the light source and reflected from an object; and
first, second, third, and fourth transistors coupled to the first photoelectric conversion region and that transfer charge from the first photoelectric conversion region,

wherein, in a plan view, gates of the first, second, third, and fourth transistors are arranged at a periphery of the first photoelectric conversion region in a first symmetrical pattern.

(18) The system of one or more of (1) to (17), wherein the first symmetrical pattern has line symmetry along a first direction and along a second direction perpendicular to the first direction.
(19) The system of one or more of (1) to (18), wherein the first pixel further comprises fifth and sixth transistors coupled to the photoelectric conversion region and that transfer charge from the first photoelectric conversion region, wherein, in the plan view, the gates of the first, second, third, fourth transistors and gates of the fifth and sixth transistors are arranged at the periphery of the first photoelectric conversion region in a second symmetrical pattern that maintains the symmetry of the first symmetrical pattern.
(20) An imaging device, comprising:

a first pixel including:
a photoelectric conversion region; and
a plurality of pixel transistors; and
at least four transistors that transfer charge from the photoelectric conversion region to respective ones of the plurality of pixel transistors,

wherein, in a plan view, the at least four transistors and the plurality of pixel transistors have line symmetry along at least one direction.

Any one or more of the aspects/embodiments as substantially disclosed herein.

Any one or more of the aspects/embodiments as substantially disclosed herein optionally in combination with any one or more other aspects/embodiments as substantially disclosed herein.

One or more means adapted to perform any one or more of the above aspects/embodiments as substantially disclosed herein.

It is claimed:

1. An imaging device, comprising:
a first pixel including:
a first photoelectric conversion region; and
first, second, third, and fourth transistors coupled to the first photoelectric conversion region and that transfer charge from the first photoelectric conversion region,
wherein, in a plan view, gates of the first, second, third, and fourth transistors are arranged at a periphery of the first photoelectric conversion region in a first symmetrical pattern.

2. The imaging device of claim 1, further comprising:
a second pixel including:
a second photoelectric conversion region; and
fifth, and sixth, seventh, and eighth transistors coupled to the second photoelectric conversion region,
wherein, in the plan view, gates of the fifth, sixth, seventh, and eighth transistors are arranged at a periphery of the second photoelectric conversion region in a second symmetrical pattern.

3. The imaging device of claim 2, wherein, in the plan view, pixel transistors of the first pixel and the second pixel are aligned with one another in a first direction.

4. The imaging device of claim 3, wherein the pixel transistors include selection transistors, amplification transistors, and reset transistors.

5. The imaging device of claim 2, wherein the first, second, third, fifth, sixth, and seventh transistors transfer charge of interest, and wherein the fourth and eighth transistors transfer overflow charge.

6. The imaging device of claim 2, wherein the first pixel and the second pixel are adjacent to one another such that the fourth transistor and the eighth transistor share drain regions.

7. The imaging device of claim 2, wherein the first pixel and the second pixel include pixel transistors with point symmetry.

8. The imaging device of claim 1, wherein the first pixel includes a first amplification transistor that amplifies a signal output from the first transistor, and a second amplification transistor that amplifies a signal output from the second transistor, and wherein the first amplification transistor and the second amplification transistor share drain regions.

9. The imaging device of claim 8, wherein the first pixel includes a third amplification transistor that amplifies a signal output from the third transistor, and wherein the third amplification transistor and a fourth amplification transistor of another pixel different than the second pixel share drain regions.

10. The imaging device of claim 1, wherein the first pixel further comprises:
fifth and sixth transistors coupled to the first photoelectric conversion region and that transfer charge from the first photoelectric conversion region, wherein, in the plan view, the gates of the first, second, third, fourth transistors and gates of the fifth and sixth transistors are arranged at the periphery of the first photoelectric conversion region in a second symmetrical pattern that maintains the symmetry of the first symmetrical pattern.

11. The imaging device of claim 10, wherein the first, second, third, and fourth transistors transfer charge of interest, and wherein the fifth and sixth transistors transfer overflow charge.

12. The imaging device of claim 10, wherein the first pixel further comprises pixel transistors coupled to the first, second, third, and fourth transistors, and wherein, in the plan view, the pixel transistors and the first, second, third, fourth, fifth, and sixth transistors have line symmetry along a first direction and along a second direction perpendicular to the first direction.

13. The imaging device of claim 10, wherein the gates of the first and second transistors are shorted to one another, and wherein the gates of the third and fourth transistors are shorted to one another.

14. The imaging device of claim 10, wherein the first, second, third, and fourth transistors are connected to respective signal lines that receive respective transfer signals having different phases, wherein the different phases are determined based on a driving signal that drives a light source.

15. The imaging device of claim 1, wherein the first pixel further comprises wirings that electrically connect floating diffusions of the first pixel to respective amplification transistors of the first pixel, and wherein, in the plan view, the wirings include dummy portions that extend beyond a connection point to the respective amplification transistors.

16. The imaging device of claim 1, wherein the first, second, and third transistors are connected to respective signal lines that receive respective transfer signals having different phases, wherein the different phases are determined based on a driving signal that drives a light source.

17. A system comprising:
a light source that emits light based on a driving signal;
an imaging device, comprising:
a first pixel including:
a first photoelectric conversion region that receives light emitted by the light source and reflected from an object; and
first, second, third, and fourth transistors coupled to the first photoelectric conversion region and that transfer charge from the first photoelectric conversion region,
wherein, in a plan view, gates of the first, second, third, and fourth transistors are arranged at a periphery of the first photoelectric conversion region in a first symmetrical pattern.

18. The system of claim 17, wherein the first symmetrical pattern has line symmetry along a first direction and along a second direction perpendicular to the first direction.

19. The system of claim 17, wherein the first pixel further comprises fifth and sixth transistors coupled to the first photoelectric conversion region and that transfer charge from the first photoelectric conversion region, wherein, in the plan view, the gates of the first, second, third, fourth transistors and gates of the fifth and sixth transistors are arranged at the periphery of the first photoelectric conversion region in a second symmetrical pattern that maintains the symmetry of the first symmetrical pattern.

20. An imaging device, comprising:
a first pixel including:
a photoelectric conversion region; and
a plurality of pixel transistors; and
at least four transistors that transfer charge from the photoelectric conversion region to respective ones of the plurality of pixel transistors,
wherein, in a plan view, the at least four transistors and the plurality of pixel transistors have line symmetry along at least one direction.
